(19) United States
(12) Patent Application Publication
(10) Pub. No.: US 2011/0132437 A1
(43) Pub. Date: Jun. 9, 2011

(54) METHODS TO BOND OR SEAL GLASS PIECES OF PHOTOVOLTAIC CELL MODULES

(76) Inventors: Alan Kost, Tucson, AZ (US); Charles Qian, Gilbert, AZ (US); Katherine Lu, Tucson, AZ (US)

(21) Appl. No.: 12/960,306

(22) Filed: Dec. 3, 2010

Related U.S. Application Data
(63) Continuation-in-part of application No. 12/331,744, filed on Dec. 10, 2008.
(60) Provisional application No. 61/012,750, filed on Dec. 10, 2007.

(51) Int. Cl. H01L 31/048; B23K 31/02

(52) U.S. Cl. 136/251; 228/121

(57) ABSTRACT

The apparatus and methods of the present disclosure, in a broad aspect, provide methods for bonding or sealing pieces of glass of photovoltaic cell modules. These methods include providing the first piece of glass, providing a second piece of glass, providing a photovoltaic cell between the first piece of glass and second piece of glass, providing an amount of solder to at least one solder contact area disposed on at least one of the first or second pieces of glass, bringing the first and second pieces of glass into contact at the at least one solder contact area, and heating the solder to about the melting point or working point of the solder to provide the first and second pieces of glass with a bond or seal at the at least one solder contact area.

### CROSS REFERENCE TO RELATED APPLICATIONS

This application is a continuation-in-part of U.S. patent application Ser. No. 12/331,744 filed Dec. 10, 2008, which claims the benefit of U.S. Provisional Application No. 61/012,750 filed on Dec. 10, 2007, the entire disclosures of which are hereby incorporated by reference.

### FIELD OF THE INVENTION

The present disclosure generally relates to apparatus and associated methods for bonding or sealing pieces of glass in the manufacture of photovoltaic cell modules.

### BACKGROUND

Electricity production generally requires electricity generation which involves converting non-electrical energy to electricity. For electric utilities, it is the first process in the delivery of electricity to consumers. The other processes, electric power transmission and electricity distribution, are normally carried out by the electrical power industry. Electricity is most often generated at a power station by electromechanical generators, primarily driven by heat engines fueled by chemical combustion or nuclear fission.

Production of electricity from carbon-based fuels has a significant drawback. Emissions from electricity generation account for much of the world's greenhouse gas emissions, and in the United States, electricity generation accounts for nearly 40% of emissions, the largest of any source. The greenhouse effect, the process by which absorption and emission of infrared radiation by atmospheric greenhouse gases warms the planet's lower atmosphere and surface, is caused by increased world greenhouse gas emissions.

Human activity since the industrial revolution has increased the concentration of various greenhouse gases, leading to increased radiative forcing from carbon dioxide (CO₂), methane (CH₄), tropospheric ozone (O₃), chlorofluorocarbons (CFCs) and nitrogen oxides (NOₓ). For example, the atmospheric concentrations of CO₂ and CH₄ have increased by 31% and 149% respectively since the beginning of the industrial revolution in the mid-1700s. Fossil fuel burning has produced approximately three-quarters of the increase in CO₂ from human activity over the past 20 years.

The present atmospheric concentration of CO₂ is about 385 parts per million (ppm) by volume. Future CO₂ levels are expected to rise due to ongoing burning of fossil fuels and land-use change. The rate of rise will depend on economic, sociological, technological, and natural developments, all of which have proven at least somewhat unpredictable.

Given the harmful effects of global warming and finite sources of available coal and petroleum, other methods of producing electricity have been pursued. One such method is the use of photovoltaics. A photovoltaic cell is a device that converts light energy into electrical energy. A solar cell specifically captures energy from sunlight, while producing zero emissions. Although the use of solar energy had historically been limited to remote places where electrical power lines could not easily reach, government regulations have been imposed to produce at least a certain percentage of electricity from renewable sources of energy. Policies may increasingly make solar energy production less uncommon and perhaps even mainstream.

Solar cells are often electrically connected and encapsulated as a module. Photovoltaic cell modules often have a sheet of glass on the front (sun up) side, allowing light to pass while protecting the semiconductor wafers from the elements (rain, hail, etc.). On the bottom, when there is a thin film photon absorbing material a glass substrate generally is needed. Typically, only thin film solar cells such as CIGS, CdTe, and amorphous silicon have thin film absorbing material. Crystalline silicon cells, currently the most common type, absorb light in thick, bulk pieces of semiconductor. Solar cells are also usually connected in series, creating an additive voltage. Connecting cells in parallel will yield a higher current. Modules are then interconnected, in series or parallel, or both, to create an array with the desired peak direct current (DC) voltage and current.

The top and bottom pieces of glass of various photovoltaic modules (especially those having thick film solar cells) generally have to be bonded or sealed so that they stay in place to serve as protective or substrate layers. Such bonding or sealing ideally has maximum longevity and minimal proneness for degradation, for example, through oxidation and moisture ingress. Prior glass sealing compositions such as silicone, can dry out and lose their ability to maintain a seal or bond after prolonged exposure to sunlight and other elements. Oxidation and ingress of moisture are detrimental to solar cells. Efficient and effective methods of sealing such cells are an ongoing goal in the art. Further, prior techniques required melting of high temperature sealing materials which had the potential to damage the solar cell. As a result, there is a significant need in the art for novel apparatus and associated methods for bonding or sealing pieces of glass useful for photovoltaic cell modules.

### SUMMARY

These and other objects are achieved by the apparatus and methods of the present disclosure which, in a broad aspect, provide means for bonding or sealing pieces of glass of photovoltaic cell modules. Surprisingly, suitably engineered and applied solders provide bonds or seals of glass pieces of photovoltaic cell modules which have increased longevity and decreased susceptibility to degradation from the elements, such as moisture and prolonged exposure to sunlight, as compared to existing methods used to bond or seal pieces of glass of photovoltaic cell modules.

Silicone has been used as a caulk on the outside of a module to prevent moisture from attacking a photovoltaic cell. A thermoplastic such as ethyl vinyl acetate (EVA) can be used to affix the cell to the cover glass. In alternative embodiments of the present disclosure, the instant glass or metal solders can be used one of two ways: it can be used with a thermoplastic such as EVA, in which case its purpose is to prevent moisture and other outside elements from entering the module (sealing); or it can be used without the EVA in which case it performs a dual role—preventing moisture from reaching the cell (sealing) and affixing (bonding) the glass to the cell.

Described herein generally are methods of bonding a first piece of glass and a second piece glass of a photovoltaic cell module comprising providing said first piece of glass having a planar surface; providing said second piece of glass having a second planar surface; providing a photovoltaic cell between said first piece of glass and said second piece of glass; providing an amount of solder to at least one solder contact area disposed on at least one of said first or second pieces of glass, wherein said solder comprises gold; heating said solder to about the melting or working point of said solder; and bonding said first piece of glass and said second piece glass thereby sealing said photovoltaic cell module from moisture.

In one embodiment, the solder comprises tin, indium or a combination thereof. The solder can further comprise gold at an amount of about 0.1% to about 1%. The solder with gold present can have a composition of about 49.9% Sn/49.9% In/0.2% Au or about 49.25% Sn/49.25% In/0.5% Au.

In other embodiments, the solder further comprises glass having PbO, ZnO, B₂O₃, Bi₂O₃, Ag₂O, Al₂O₃, Li₃O, NaO, or SnO; or a combination thereof.

The photovoltaic cell modules further include a polymer encapsulating layer located between the first piece of glass and the photovoltaic cell, and wherein the polymer encapsulating layer comprises ethyl vinyl acetate.

Further described herein are methods of bonding a first piece of glass and a second piece glass of a photovoltaic cell module comprising providing said first piece of glass having a planar surface; providing said second piece of glass having a second planar surface; providing a photovoltaic cell between said first piece of glass and said second piece of glass; providing at least one brazing strip to at least one solder contact area disposed on said first piece of glass and said second pieces of glass; further providing at least one strip of solder foil to at least one brazing strip; heating said at least one strip of solder foil to about the melting or working point of the solder foil; and bonding said first piece of glass and said second piece glass thereby sealing said photovoltaic cell module from moisture.

The solder can in some embodiments comprise tin, indium or a combination thereof. The heating of the solder can take less than about one second. In some embodiments, the solder further comprises glass comprises PbO, ZnO, B₂O₃, Bi₂O₃, Ag₂O, Al₂O₃, Li₃O, NaO, or SnO; or a combination thereof.

In other embodiments, photovoltaic cell modules further include a polymer encapsulating layer located between said first piece of glass and said photovoltaic cell, and wherein said polymer encapsulating layer comprises ethyl vinyl acetate.

Generally, the methods described herein form photovoltaic cell module. As such, photovoltaic cell modules comprising a first piece of glass; a second piece of glass; a photovoltaic cell located between said first and second pieces of glass; and a gap around the periphery and between said first and second pieces of glass filled with a solder, wherein the solder seals said photovoltaic cell module from moisture are described herein.

In one embodiment, the solder comprises tin, indium or a combination thereof. The solder can further comprise gold present at an amount of about 0.1% to about 1%. In some embodiments the solder can have a composition of about 49.9% Sn/49.9% In/0.2% Au or about 49.25% Sn/49.25% In/0.5% Au. In other embodiments, the solder further comprises glass comprises PbO, ZnO, B₂O₃, Bi₂O₃, Ag₂O, Al₂O₃, Li₃O, NaO, or SnO; or a combination thereof.

In still other embodiments, photovoltaic cell modules further include a polymer encapsulating layer located between said first piece of glass and said photovoltaic cell, and wherein said polymer encapsulating layer comprises ethyl vinyl acetate.

In yet other embodiments, photovoltaic cell modules comprising a brazing strip between said first piece of glass and said solder. The photovoltaic cell modules can also comprise a brazing strip between said second piece of glass and the solder.

In some embodiments, the soldering process takes place in an inert atmosphere such as argon or nitrogen.

### BRIEF DESCRIPTION OF THE DRAWINGS

FIG. 1 illustrates a photovoltaic cell module with the top and bottom pieces of glass sealed with a presently disclosed solder.

FIG. 2 illustrates a sealed photovoltaic cell module with the top and bottom pieces of glass sealed with a presently disclosed glass solder, showing local heat application points.

FIG. 3A illustrates a sealed photovoltaic cell module with a solder seal and FIG. 3B illustrates a sealed photovoltaic cell module wherein a nanofoil bonding material was used and flanked by a brazing layer.

FIG. 4 illustrates a heating apparatus used to bond glass pieces according to the present description.

FIGS. 5A-5C illustrate samples exposed to ESPC for DH=0, DH=148 h, and a porous region exhibiting moisture ingress, respectively.

FIGS. 6A-6D illustrate color index changes measured for the CoCl₂ coating.

FIGS. 7A-7F illustrate samples exposed to HAST for various amounts of time.

FIGS. 8A-8D illustrate color index changes measured for the CoCl₂ coating exposed to HAST.

FIGS. 9A-9D illustrate Cerroseal 35 solder with different exposure times and circumstances.

FIGS. 10A-10C illustrate XPS depth profile analysis for Cerroseal 35 alloy applied by solder iron on microslides after DH=0 h (9A), DH=351 hr (9B), DH=981 hr (9C) exposure in the ESPC chamber.

### DETAILED DESCRIPTION

A photovoltaic cell (e.g., solar cell) converts light energy to electrical energy by photogenerating charge carriers (e.g., electrons and holes) in at least one photon-absorbing material such as a semiconductor (e.g., silicon, CIGS, CdTe, CIS, organic polymer, or combinations thereof). Charge carriers (e.g., electrons) move toward electrically-conductive contacts where electrical energy may then be further transported and/or utilized. This photovoltaic effect often occurs within a “module.” A photovoltaic module typically contains at least one photon-absorbing semiconductor material, elements to protect or serve as a substrate to the at least one photon-absorbing material, and electrical contacts/wiring.

Described herein are methods to join, bond or seal two pieces of glass. Typically these two pieces are the top protective glass layer which protects the photovoltaic cell from the elements (rain, hail, etc.) and a glass substrate layer onto which photon absorbing materials such as thin film photon absorbing materials may be placed. Because previous bonding compositions have the disadvantage of degrading or otherwise being rendered unsuitable to maintain a glass bond over time, particularly if the composition was exposed to the elements, the present novel advantages methods for bonding or sealing glass are provided.

One embodiment of the present methods for bonding or sealing includes: providing a first piece of glass having a planar surface, providing a second piece of glass having a second planar surface, providing a photovoltaic cell between the first piece of glass and second piece of glass, providing an amount of solder to at least one solder contact area disposed on at least one of the first or second pieces of glass, bringing the first and second pieces of glass into contact at the at least one solder contact area, and heating the solder to about the melting or working point of the solder to provide the first and second pieces of glass with a bond or seal at the at least one solder contact area.

Solar cells are often electrically connected and encapsulated as a module. Photovoltaic cell modules often have a sheet of glass on the front (sun up) side, allowing light to pass while protecting the semiconductor wafers from the elements (rain, hail, etc.). The first piece of glass as herein used is glass typically used as a top protective layer of a photovoltaic cell module. This piece of glass can be considered then as the layer that most directly faces a light source such as the sun. The second piece of glass as herein used refers to glass which is typically used as the glass substrate upon which generally a thin film photon absorbing material is placed. Thin film photon absorbing layers, unlike bulk silicon, are deposited on a substrate that provides structural integrity.

A photovoltaic cell is provided between the first piece of glass and the second piece of glass. A photovoltaic cell includes at least one semiconductor material which may be used for photoabsorption of photons. In addition to silicon, a semiconductor material which may be used for photo-absorption of photons in accordance with the present disclosure is copper indium gallium diselenide (CIGS). CIGS can be configured in at least one layer, preferably in thin-film composites. Thin-film technologies reduce the amount of light absorbing semiconductor material required to make a photo-voltaic cell. This can lead to reduced costs when compared to solar cells made from bulk materials.

Higher efficiencies may be obtained by using optics to concentrate the incident light. The use of gallium increases the optical bandgap of the CIGS layer as compared to CIS (another photo-absorbing semiconductor material which may be utilized according to the present disclosure). Selenium allows for better uniformity across the layer of CIGS and so the number of recombination sites in the film are reduced which benefits the quantum efficiency and thus the conversion efficiency. CIGS films may be manufactured by various methods. These include vacuum-based processes which co-evaporate or co-sputter copper, gallium, and indium, and then anneal the resulting film with a selenide vapor to form a final CIGS structure. Non-vacuum based alternative processes deposit nanoparticles of the precursor materials on a substrate and sinter them in situ. Also, CIGS can be printed directly onto molybdenum coated glass sheets.

Cadminum telluride (CdTe) is another photon-absorbing semiconductor material which may be utilized within the scope and teachings of the present disclosure. CdTe is an efficient light-absorbing material which can be used primarily in thin-film photovoltaic cells. CdTe is relatively easy to deposit and therefore is considered suitable for large-scale production.

CIS is an abbreviation for general chalcopyrite films of copper indium selenide. An example is CuInSe₂ which is of interest for photovoltaic applications including elements from groups I, III and VI in the periodic table. CIS has high optical absorption coefficients and versatile optical and electrical characteristics which may be manipulated and tuned. CIS is a photon-absorbing semiconductor which may be utilized within the scope and teachings of the present disclosure. CIS most often is used to make a thin-film of photon absorbing material for a solar cell.

Organic polymers may also be used as a photon-absorbing semiconductor material. These materials may be made, for example, from polymers and small molecule compounds such as polyphenylene vinylene, copper phthalocyanine (a blue or green organic pigment) and carbon fullerenes. Organic polymers may be especially important for photovoltaic cells in which mechanical flexibility and disposability are important.

It is within the scope and teachings of the present disclosure that the above-mentioned photon-absorbing semiconductor materials may be used alone or in combination. Also, the materials may be in more than one layer, each layer having a different type of photon-absorbing semiconductor material or having combinations of the photon-absorbing semiconductor materials in separate layers. One of ordinary skill in the art would be able to optimally configure the amount and construction of the materials to maximize the quantum and overall efficiencies of a photovoltaic cell in accordance with the present disclosure.

Optionally, at least one cover layer is located above the at least one photon-absorbing semiconductor material for photovoltaic cell according to the present disclosure. The cover layer(s) may serve various purposes. This layer can serve as an n-type or p-type semiconductor. Generally, a commonly known solar cell is configured as a large-area p-n junction. A p-n junction is a junction formed by combining p-type and n-type semiconductors together in close contact. The term junction refers to the region where the two regions of the semiconductors meet. It can be thought of as the border region between the p-type and n-type blocks. Free carriers created by light energy are separated by the junction and contribute to current.

When the material is silicon, n-type dopant is diffused into one side of a p-type wafer or vice versa. If a piece of p-type silicon is placed in intimate contact with a piece of n-type silicon, then a diffusion of electrons occurs from a region of high electron concentration (the n-type side of the junction) into a region of low electron concentration (p-type side of the junction). When electrons diffuse across a p-n junction, they recombine with holes on the p-type side. The diffusion of carriers does not happen indefinitely however, because of an electric field which is created by the imbalance of charge immediately either side of the junction which this diffusion creates. The electric field established across the p-n junction creates a diode that promotes current flow in only one direction across the junction. Electrons may pass from the n-type side into the p-type side, and holes may pass from the p-type side to the n-type side. This region where electrons have diffused across the junction is called the depletion region because it no longer contains any mobile charge carriers.

An example of an n-type semiconductor which can form the n-type side of a p-n junction within the scope and teachings of the present disclosure is cadmium sulfide (CdS). It is yellow in color and is a semiconductor. Cadmium sulfide can be produced from volatile cadmium alkyls. An example is the reaction of dimethylcadmium with diethyl sulfide to produce a film of CdS using MOCVD techniques. It is important to point out that CdS may absorb those photons having a wavelength which may otherwise be usable or capable of absorption by a photon-absorbing semiconductor material such as CIGS. One of ordinary skill in the art will recognize that this may be partly why CdS generally has been deposited as a very thin film. However, CdS is often a necessary part of a photovoltaic cell and absorption of otherwise usable photons by CdS, especially in the blue range of the solar radiation which reaches the earth, reduces the quantum efficiency of a photon-absorbing semiconductor material and, therefore, the overall efficiency of a solar cell.

Alternatively, the cover layer may have at least one additional conductive layer. For example, these may be ZnO and/or ITO (indium tin oxide), or a combination thereof. These conductors of electrical charge may be, for example, in the form of thin films. These additional conductive layers may be engineered to be as transparent as possible to allow light to pass through it so that it may reach the photon-absorbing semiconductor layer underneath. However, one of ordinary skill in the art will recognize that the at least one additional conductive layer may also, like the CdS layer, absorb photons which would otherwise be useful if absorbed by the photon-absorbing semiconductor material underneath. The additional conductive layer(s) can serve as ohmic contacts to transport photogenerated charge carriers away from the light absorbing material.

It is also within the scope and teaching of the present disclosure alternatively to include metal contacts which are located nearer to the top (closer to the sun) of a photovoltaic cell. Because these metal contacts are located nearer to the top, it would be preferable that they have the least surface area as possible to allow passage of external photons to the at least one photon-absorbing semiconductor materials located underneath.

As described herein, presently disclosed photovoltaic cells alternatively also includes at least two electrically-conductive materials located above and below the at least one photon-absorbing semiconductor material. An example of this material within the scope and teachings of the present disclosure is molybdenum. Further alternatively, molybdenum is the conductive material below the at least one photon-absorbing material and a metal electrode is the electrically-conductive material above the at least one photon-absorbing material. Generally, the ability of molybdenum to withstand extreme temperatures without significantly expanding or softening makes it useful in applications that involve intense heat, including the manufacture of aircraft parts, electrical contacts, industrial motors, and filaments.

As used herein when the first and second pieces of glass of a photovoltaic cell module are “bonded” with the disclosed solders, the strength of the two glasses being held together is primarily due to the action or qualities of the provided solders. When the first and second pieces of glass of a photovoltaic cell module are “sealed,” the strength of the two glasses being held together is not primarily due to the action or qualities of the provided solders. When a polymer encapsulating layer such as ethyl vinyl acetate is provided, this polymer encapsulating layer adheres to a thin film photon absorbing material such as CIGS which has been adhered to a glass substrate, or it could be to another layer of a photovoltaic cell. The polymer encapsulating layer also adheres to the top protect glass (or the first piece of glass). Heating and setting of the polymer encapsulating layer bonds the polymer encapsulating layer to the top glass and to the photon absorbing layer. This thus provides bonding between the top glass and bottom glass.

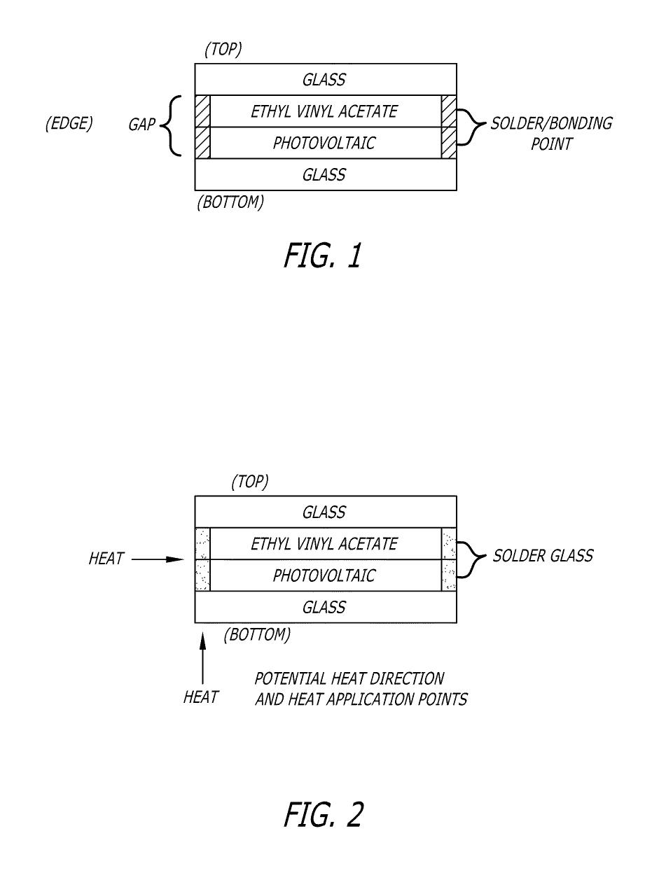

This is illustrated by FIGS. 1 and 2. In FIG. 1, the top glass (sun facing) is bonded to ethyl vinyl acetate which is bonded to the photovoltaic cell or photon absorbing layer of such a cell. This layer is bonded to the underlying glass substrate. Therefore, heating the polymer encapsulating layer such as ethyl vinyl acetate, and cooling it provides an enclosure of a photovoltaic cell where the two ends are two pieces of glass (top protective and substrate).

Ethylene vinyl acetate or ethyl vinyl acetate (also known as EVA) is the copolymer of ethylene and vinyl acetate. The weight percent vinyl acetate usually varies from 10 to 40% with the remainder being ethylene. It is a polymer that approaches elastomeric materials in softness and flexibility, yet can be processed like other thermoplastics. The material has good clarity and gloss, barrier properties, low-temperature toughness, stress-crack resistance, hot-melt adhesive water proof properties and resistance to UV radiation. EVA has little or no odor and is competitive with rubber and vinyl products in many electrical applications.

In one embodiment, the first piece of glass and the second piece of glass are bonded, or soldered, with a distance of about 5, about 4, or about 3 μm between the planar surfaces. Alternatively, first piece of glass and the second piece of glass are bonded with a distance of about 100 μm, or about 200 μm, or about 300 μm to about 600 μm, or about 500 μm, or about 400 μm between the planar surfaces.

Solder is provided to solder contact area(s) disposed on at least one of the first or second pieces of glass. Solder as used herein, in order to simplify or otherwise improve application maybe provided in several forms including tape, foil, nanofoil, in a solvent (e.g. water), in a binder (e.g., paste or gel) a combination thereof, or the like. Heating creates the bonds or seals in accordance with the present disclosure. The heating temperature may be important for glass bonding applications used to create enclosures, and as used herein for a photovoltaic cell module, for temperature sensitive components, e.g. photovoltaic cells and electrical components. When the first and second pieces of glass are brought together they should contact at least at one or more of the solder contact areas. The heating brings the solder to about its melting point or working point. Working point as herein used refers to the temperature required for the present solders to reach for them to be able to properly bond or seal the pieces of glass of a photovoltaic cell module. Metal solder is usually heated to about its melting point. For glass solder, a softening temperature is usually specified but sealing may be carried out at a higher working temperature. Cooling provides the first and second pieces of glass with a bond or seal at the at least one solder contact area.

In one embodiment, the solder comprises at least one metal. Four elements are generally used for metal solders to seal or bond pieces of glass of photovoltaic cell modules. These are tin (Sn), bismuth (Bi), indium (In) and zinc (Zn). The melting points of these elements are 232° C., 271° C., 156.7° C. and 419° C. respectively. Because In is currently expensive, Sn, Bi and Zn are the more preferred for metal solder. These may be in the form of metal alloys as well. For example, 58% by weight Bi and 42% by weight Sn allow has a melting temperature of 137° C. This melting temperature is relatively low and therefore lessen the risk of damaging the photon absorbing material of the photovoltaic cell such as CIGS.

Exemplary solders comprise alloys of the metals described above. The alloys can include Sn and In, for example. In an exemplary embodiment, the solder alloy is a 50%/50% mixture of Sn/In. Such a solder alloy is commonly termed CERROSEAL® 35 (Marmon Flow Products LLC, Chicago, Ill.) and is commonly sold as a wire, but other forms are available. In another exemplary embodiment, the solder alloy is a 52%/48% mixture of Sn/In. Such a solder alloy is commonly termed WS118.

In one embodiment, gold (Au) was surprisingly found to be an advantageous component of the above solders and alloys. Gold can be added at an amount of about 0.1% to about 1%. For example, the gold is present at about 0.1%, 0.2%, 0.3%, 0.4%, 0.5%, 0.6%, 0.7%, 0.8%, 0.9% or 1%. The gold can also be present in ranges, for example, from about 0.1% to about 0.5%, about 0.5% to about 1%, about 0.1% to about 0.3%, from about 0.3% to about 0.6% from about 0.6% to about 1%.

In some embodiments, the solder utilizes fractionalized heating. Fractionalized heating describes heating that limits the time a solder is heated, reduces the amount of heat needed, reduces the upper limit of heat needed, or a combination thereof. Such solder or a solder system can be heated for a fraction of a second to melt and bond the glass pieces. Exposing modules to elevated temperatures for such a short period of time reduces the risk of damaging the solar cells themselves. An exemplary solder system is NANOFOIL® (Reactive NanoTechnologies, Inc., Hunt Valley, Md.).

NANOFOIL®, or simply nanofoil comprises thousands of nanoscale metal layers that are vapor deposited on a substrate. In other embodiments, the nanolayers are aluminum and nickel, or tin and inudium, or tin, indium and gold. Virtually any combination of metal solder can be combined in nanolayers to form a nanofoil as described. Generally, the nanofoils are lead free for safety.

To use the nanofoils, a small pulse of local energy from an electric, optical or thermal source activates the chemical reaction between the nanolayers in the foil. As the reaction proceeds through the foil, temperatures become very elevated (e.g. up to 1,500° C.) for a short period of time. However, that short period of time is long enough to reflow solder. The average amount of time for the reactions to start after activation fo the foil is about 10 milliseconds. Literally, within seconds, the soldered glass can be handled because the intense heat was only present for a fraction of a second.

This short heating time allows for controlled fabrication of photovoltaic solar cell modules without degradation of the solar cell from excess heat. Further, nanofoil can be localized instead of having to heat the entire module and preheating the solder.

Another solder within the scope and teachings of the present disclosure which may be used to seal or bond pieces of glass of a photovoltaic cell module is a binary Sn—Al lead free solder alloy having a melting point of about 231° C. It is called SONIC SOLDER® made by EWI®. This solder contains Sn an Al which are two fairly abundant and inexpensive materials currently. Second this solder can be used with ultrasonic soldering—a procedure that allows the solder to bind to glass without the use of a primer layer such as chromium.

In another embodiment, the solder comprises glass. The solder may also comprise both glass and at least one metal. The glass in the solder may comprise PbO, ZnO, B₂O₃, Bi₂O₃, Ag₂O, Al₂O₃, Li₃O, NaO, or SnO; and combinations thereof. In a preferred embodiment, the glass in the solder comprises PbO, B₂O₃ and ZnO. Alternatively, the glass in the solder comprises 55% to 65% by weight PbO, 5% to 15% by weight B₂O₃, and 15% to 25% by weight ZnO. A typical composition of solder glass within the scope and teachings of the present disclosure is 62% PbO, 12% B₂O₃, and 21% ZnO which has a softening temperature of 380° C. (Vacuum Sealing Techniques,” A. Roth, (AIP Press, Woodbury, N.Y., 1994), Table 3.6). Such a glass mixture can be made by grinding the oxides into powders and mixing the powders. Water may be added to make a paste of the powder and this can be painted onto a bottom piece of glass. The glass then can be heated to remove water from the paste leaving a solder glass film on the glass. A top sheet of glass can be placed on top of the bottom sheet to form the solder glass combination. The solder may be heated with a laser or with a lamp in alternative embodiments to melt and form a bond between the two glass sheets.

Further, when using a nanofoil or even using metal solder, a brazing layer can be applied to the solder contact areas on the glass before the nanofoil or metal solder is applied. Braze is generally available as rod, ribbon, powder, paste, cream, wire and preforms (such as stamped washers). The braze can comprise a material selected from the group consisting of aluminum (Al), silicon (Si), copper (Cu), phosphorous (P), Zn, Au, silver (Ag), nickel (Ni), alloys thereof and foils thereof. Exemplary brazing alloys include, but are not limited to aluminum-silicon, copper-phosphorous, copper-zinc (brass), gold-silver, nickel alloy, and the like. In one embodiment, the braze layer is copper.

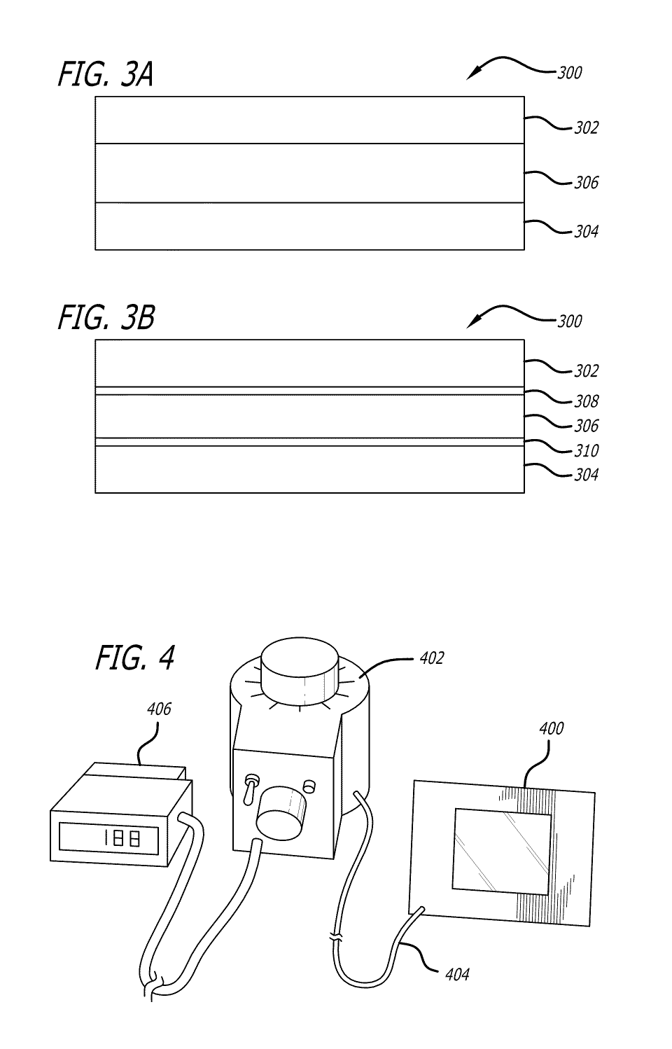

As illustrated in FIG. 3A, in an exemplary embodiment, soldered module 300 includes first glass plate 302 and second glass plate 304 joined by solder 306. Illustrated in FIG. 3B is another example embodiment where first glass plate 302 and second glass plate 304 are joined by solder 306, interfaced by first brazing layer 308 and second brazing layer 310. In one example embodiment, solder 306 is a nanofoil and first brazing layer 308 and second brazing layer 310 are copper.

To produce solders with a desired thermal expansion coefficient, “fillers” can be added such as SiO₂, ZrSiO₄, ZnO, or An₃(PO₄)₂; and combinations thereof. Generally, when the temperature of a substance changes, energy that is stored within the intermolecular bonds between atoms changes. When stored energy increases, so does the length of the molecular bonds. As a result, solids typically expand in response to heating and contract on cooling; this dimensional response to temperature change is expressed by its coefficient of thermal expansion. Different coefficients of thermal expansion can be defined for a substance depending on whether the expansion is measured by: linear thermal expansion, area thermal expansion, or volumetric thermal expansion. These characteristics are closely related. A volumetric thermal expansion coefficient can be defined for both liquids and solids. A linear thermal expansion can only be defined for solids, and is common in engineering applications. Some substances expand when cooled, such as freezing water, so they have negative thermal expansion coefficients. Preferably, when glass solder is used, selecting solder and pieces of glass that have relatively close coefficients of thermal expansion results in more resilient bonds.

In a preferred embodiment, the herein provided solders are free of lead. Lead is a poisonous metal that can damage nervous connections (especially in young children) and cause blood and brain disorders. Because of its low reactivity and solubility, lead poisoning usually only occurs in cases when the lead is dispersed, like when sanding lead based paint, or long term exposure in the case of pewter tableware. Long term exposure to lead or its salts (especially soluble salts or the strong oxidant PbO₂) can cause nephropathy, and colic-like abdominal pains.

If the solder process is performed in an ambient open air environment, the solder may require the use of flux to prevent oxide formation at the solder joint. Oxides can destroy photovoltaic cells and as such, in some embodiments, need to be avoided.

It is also within the scope of the present description that the soldering process be completed in an inert atmosphere, for example in argon or nitrogen gas (N₂). Such a process is more easily completed in a vacuum chamber filled with an inert environment. Processing in an inert environment is particularly important when flux is to be used as oxides are easily formed in an ambient environment.

In another embodiment, on the bottom side of the first piece of glass may be coated with at least one anti-reflective coating. Especially, when no polymer encapsulating layer is present and solder contact area(s) are the edges that a first piece of glass and a second pieces of glass respective may comprise, there may be reflection because of a gap that might be present. This gap typically would contain air and because of the different refractive indices, reflection problems may occur. Application of one or more anti-reflective coatings may alleviate this problem.

Anti-reflective or antireflection (AR) coatings are a type of optical coating applied to the surface of lenses and other optical devices to reduce reflection. In some applications such as those concerning the present disclosure, the primary benefit is the elimination of the reflection itself, such as a coating on eyeglass lenses that makes the eyes of the wearer more visible, or a coating to reduce the glint from a covert viewer's binoculars or telescopic sight.

Many coatings consist of transparent thin film structures with alternating layers of contrasting refractive index. Layer thicknesses are chosen to produce destructive interference in the beams reflected from the interfaces, and constructive interference in the corresponding transmitted beams. This makes the structure's performance change with wavelength and incident angle, so that color effects often appear at oblique angles. A wavelength range must be specified when designing or ordering such coatings, but good performance can often be achieved for a relatively wide range of frequencies: usually a choice of IR, visible, or UV is offered.

Further, in another embodiment, before the soldering step, a bonding or sealing enhancing layer may be applied to the first and/or second pieces of glass. One example of such an enhancing layer in accordance with the scope and teachings of the present disclosure is chromium. Application of chrome may enhance the bonding of solder to the pieces of glass by bonding of solder to chrome. Chromium tenaciously bonds to glass and therefore may enhance the action of the presently provided solders.

In some embodiments, the provided solders are melted with heat. This heating may be local heating, especially when glass solder is used because higher temperatures may be required to melt glass solder compared to metal solders. If the temperature required can damage any of the components of a photovoltaic cell such as the CIGS layer, local heating to only the solder points may avoid damage. The heating may be to a temperature of about 200° C. or more, 300° C. or more, 700° C. or less, 500° C. or less, 400° C. or less, 300° C. or less, 200° C. or less, or 175° C. or less. When the provided solder comprises glass, alternatively the solder glass itself has a meting temperature of about 700° C. or less and 500° C. or less. The heat may be provided to all bonding or sealing points separately or simultaneously. The heat may be applied simultaneously to all bonding points to avoid heating and reheating, and the accompanying stress in some embodiments. In addition, glass pieces to be bonded or sealed may be preheated to a temperature at or below melting point or working point of the lowest melting point or working point constituent (e.g., the glass solder) such that the heating is conducted in stages, e.g. preheating and heating to melt solder glass. For example, the glass sheets may be pre-heated to 150° C., the solder glass applied to the intended bonding point(s), e.g the entire outer periphery of the sheet(s), and heating resumed to about 400° C., the melting point or working point of the solder glass. If the glass sheets were to enclose a photovoltaic cell, e.g. to create a photovoltaic module, the entire photovoltaic module may be preheated or heated together and the glass bonded to enclose the photovoltaic cell.

In another embodiment of the present photovoltaic cell modules, the solder comprises Sn and Bi or Si and In. In another embodiment of the present photovoltaic cell modules, the solder glass has a thermal expansion coefficient that is within about 0.5 ppm of the thermal expansion coefficient of at least one of the first piece of glass and the second piece of glass. In another embodiment of the present photovoltaic cell modules, the solder glass has a thermal expansion coefficient that is within about 0.5 ppm of the thermal expansion coefficient of at least one of said first piece of glass and said second piece of glass. In another embodiment of the present photovoltaic cell modules, the solder glass has a melting temperature of about 700° C. or less. In another embodiment of the present photovoltaic cell modules, the solder glass has a melting temperature of about 500° C. or less. In another embodiment of the present photovoltaic cell modules, the solder glass has a melting temperature of about 400° C. or less. In another embodiment of the present photovoltaic cell modules, the solder glass has a melting temperature of about 300° C. or less. In another embodiment of the present photovoltaic cell modules, the solder glass has a melting temperature of about 200° C. or less. In another embodiment of the present photovoltaic cell modules, the solder glass has a melting temperature of about 150° C. or less. In another embodiment of the present photovoltaic cell modules, the first piece of glass and the second piece of glass are rendered irregular at or near the at least one solder contact area prior to heating. In another embodiment of the present photovoltaic cell modules, the first piece of glass and the second piece of glass respectively comprise a first and second edge and the at least one solder contact area is disposed at or near at least one of the first or second edges.

In some embodiments, it may be desirable to make the surface of the glass irregular at or near the intended bonding point. For example, the surfaces may be made irregular by roughing the surface, etching the surface, providing channels or grooves in the surface, and other irregularities known to the skilled artisan. These surface irregularities may improve bonding between the solder and the glass surface. In addition, surface irregularities may provide flexibility in glass bonding geometry, e.g. the distance separating two planar glass surfaces. Methods to produce surface irregularities include mechanical means, chemical means and other means known to skilled artisans. It will be apparent that the surface irregularity should be provided at a time before the heating/bonding/sealing step.

In some embodiments, the pieces of glass may be provided in the form of sheets having peripheral edges. In some embodiments, the bonding point with a planar surface at or near the peripheral edge of one piece of glass with the planar surface at or near the peripheral edge of the other piece of glass. In other embodiments, other items may be sandwiched between the sheet of glass. In still other embodiments, the sandwiched items are not disposed at the peripheral edges of the sheets of glass, e.g. are smaller than and centered within the peripheral edges of the two sheets of glass. In that regard, applying heat only at or near the solder glass contact point at the peripheral edges of the glass sheets will be less likely to damage the sandwiched item(s). One example of a sandwiched item may be a polymer layer, e.g. a polymer encapsulating layer such as ethyl vinyl acetate, which is commonly used in photovoltaics. Another example of a sandwiched item may be a photon-absorbing material, e.g. a semiconductor. The peripheral edges in a preferred embodiment are about 1 to 2 cm in width. The edges are illustrated by FIGS. 1 and 2.

In the case of sandwiched items and for other reasons, it may be desirable to provide a gap between two bonded pieces of glass. For example, two pieces of glass may be bonded with a minimum gap of several microns in order to accommodate, for example, the layers in a thin film photovoltaic cell. In embodiments where other (e.g. those where a photovoltaic and ethyl vinyl acetate layer) items are sandwiched, the pieces of glass may be bonded with a minimum gap of about 100 μm, or about 200 μm, or about 300 μm. The maximum gap may be about 600 μm, or about 500 μm, or about 400 μm. In other embodiments, a polymer layer, e.g. ethyl vinyl acetate, may be disposed between said first and second pieces of glass and heating step includes applying heat to at least about the melting point or working point of the polymer and up to about the melting point or working point of the solder glass.

The heating may be carried out, for example, using directed light heating. Directed light heating includes, for example, heat applied to the planar surface on the piece of glass that is opposite the planar surface that will be bonded. The directed light heat may be designed such that it passes through the pieces of glass and primarily heats the solder glass. The heating may also include heating by applying a heating coil at or near the intended bonding site. The coil is heated by resistive heating, but it is the infrared light from the coil that heats the solder. Such a heating process is commonly called IR heating. Regardless of the heating mechanism, the heat may be applied directly to and through the planar surface (e.g., heat directed to cross the planar surface). In any event, it may be desirable to apply heat only at or near the intended bonding site to conserve energy and avoid damaging any items disposed between the sheets of glass. As discussed, the heat may be applied at the edges of the glass pieces, at the plane of at least one of the glass pieces or both.

The present disclosure also relates to photovoltaic cell modules with sealed or bonded first and second pieces of glass. In one embodiment, a photovoltaic cell module comprises a first piece of glass; a second piece of glass; a photovoltaic cell located between said first and second pieces of glass; wherein said first piece of glass and said second piece of glass are in contact at one or more solder contact areas; and further wherein said first and second pieces of glass are bonded or sealed with a solder at said one or more solder contact areas.

After the photovoltaic cells have been bonded using a solder as described herein, the edges of the perimeter of the cell can further be sealed from the elements using an appropriate material. Appropriate materials can include polymers, caulkings, gels, cements and the like. One exemplary polymeric material is HELIOSEAL® (ADCO Products, Inc., Michigan), PVS 101 is preferred.

In a further embodiment of the present description, the bonded and/or sealed photovoltaic solar cell modules can withstand intense elements (rain, sun, etc.) for long periods of time. For example, in one environment, the modules can withstand about 10 years, about 20 years, about 30 years, about 40 years, about 50 years, about 60 years, about 70 years, about 80 years about 90 years or 100 or more years of the elements. That is to say that even the harshest environments, for example, desert, arctic, or marine, the photovoltaic cell modules described herein can withstand such time periods without substantial degradation.

In some embodiments, the photovoltaic solar cell modules withstand at least 100 hours in a humid environment, for example damp heat at 85° C./85% relative humidity, or even a highly accelerated stress test environment. Preferably, the modules last at least about 1000 hr or more.

Unless otherwise indicated, all numbers expressing quantities of ingredients, properties such as molecular weight, reaction conditions, and so forth used in the specification and claims are to be understood as being modified in all instances by the term “about.” Accordingly, unless indicated to the contrary, the numerical parameters set forth in the specification and attached claims are approximations that may vary depending upon the desired properties sought to be obtained by the present invention. At the very least, and not as an attempt to limit the application of the doctrine of equivalents to the scope of the claims, each numerical parameter should at least be construed in light of the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements.

### EXAMPLE 1

### SLG Surface Cleaning

Soda lime glass (SLG) plates were attained of 2.32-mm thickness. The “float” (tinned) sides were checked using a black light and marked. The SLG plates needed to be cleaned in order to remove organic contaminants. To clean the SLG plates, on of two methods was used.

Method 1 involved soaked the SLG plates in a 3.0 N NaOH aqueous solution for 20 min with occasional hand-shaking. The soaked SLG plates where then rinsed and ultrasonicated in dionized water for 10 min, rinsed further, and then blow-dried.

Method 2 involved rubbing the SLG plates with diluted Billco glass-cleaning detergent solution and 10-μm pumice powders using a lint-free cloth. The rubbed SLG plates where then rinsed and ultrasonicated in dionized water for 10 min, rinsed further, and then blow-dried.

Optionally, the SLG plates cleaned using either method 1 or method 2 were further soaked/ultrasonicated in acetone for 10 min and blow-dried.

### EXAMPLE 2

### Glass Surface Wetting with Solder Alloys

After the SLG plates were cleaned, the plates where inspected and marked with “bands” or strips (2-3-mm wide) where alloys were to be applied. The plates were then heated to 140° C. on a flat hot plate with the non-Sn sides facing up. The bands or strips on the heated non-Sn side were “wetted”/applied (“pre-tinned”) with solder alloy (m.p. 118° C.), “Cerro35” is preferred over “WS118,” using a solder iron with screwdriver tip (by Weller, ETM, 3.2-mm wide) set at 177° C. (350° F. lowest setting). The application can be also done with a glass rod tipped with solder alloy melt. Pressure and rubbing were optionally needed to help better wetting.

The setup for heating is illustrated in FIG. 4. The setup was constructed by stacking a thick glass plate (not shown), a heating foil (not shown), and an aluminum plate 400 on the top. The heating to the heating foil is controlled by a transformer variac 402 and energy is transferred to the foil using cable 404. The temperature of the heating foil is measure on gauge 406. The flat surface was easier to work with than a commercial hot plate because a commercial hot plate has a curved top-plate.

For heating SLG plates, the temperature is lowered from 200° C. to 140° C. in order to more safely handle samples and to avoid potential damage to copper indium gallium (di)selenide (GIGS) solar cells.

Solder alloy Cerroseal 35 in the form of wire wets the glass surface more easily and better than Williams WS118 (52% indium/48% tin) in the form of about 0.11 mm thin foil. Both solder alloys have a (nominal) identical melting point of 118° C. The cause for this significant and important difference is not clear, although it may be due to a difference in the exact alloy composition or the age of the alloy.

The alloys were melted in advance in a small glass vial when a glass rod applicator was employed to distribute the solder alloys. This method was more troublesome and required constant heating of the glass vial and rod on a hotplate at >160° C. Alloy wire or foil was use when a Weller solder iron was used. The Weller solder iron was more a effective and convenient way to apply the solder alloy on the SLG plates. Both application methods, glass rod or solder iron, required some light rubbing and/or pressing actions.

A flat solder iron tip (screwdriver type, Weller, ETM) works better than a conical type (Weller, ETA) with better control in surface wetting, coating width, and surface coverage. Still, due to manual application and handling of heated (hot) substrates, it was difficult to produce high quality linear alloy strips of uniform thickness and width.

Pre-marked lines that defined the bands where the solder alloy strips were applied helped to couple (pair-up) two pre-tinned SLG plates with more accuracy and precision than without using the pre-marked lines.

### EXAMPLE 3

### Bonding “Pre-Tinned” SLG Pairs

Two methods were evaluated for bonding pairs of SLG plates. The first method required a hot-press between two heating plates on a mini-press at 0.25 metric tons for a total of about 5 to 8 min at about 145° C. to about 50° C. max in open air.

The second method involved a fast-cure cycle in a double-bag vacuum laminator at 1 atm, max 145° C. for 8 min. The total cycle time using the second method is about 25 min using current program settings. Industrial practice has a total cycle time of about 12 to 15 min.

The vacuum laminator was used in the initial stage but discontinued due to inadequate bonding strength. This was due to inadequate alloy thickness and coating quality. In the final stage of the project, the vacuum laminator was enlisted again because of better alloy strip coverage, thickness, and fluidity quality on the Co—SQ sample sets. One of the advantages of using the laminator was the air and moisture from the laminates (i.e., module construction), can be removed. Additionally, back-filling with Ar or dry N₂ was optional.

The average thickness of Cerroseal 35 alloy film in hot-pressed laminates was 25 μm (standard deviation of 15 μm). The large standard deviation was in part a result of thickness variation on the SLG plates. For an industrial Mo/CIGS/CdS/i-ZnO/AZO structure, the total thickness can be in the range of about 3 to 4 μm.

An inquiry regarding the needed clearance (spacing) between the two glass sheets of a CIGS module when the “non-flatness” of large glass sheets was investigated. A product inquiry unveils that a 3.3-mm thick Starphire plate of 48″×65″ has a thickness tolerance (“non-flatness”) of ±0.127 mm. Thus, a spacer of 0.25-mm max may be needed depending on the SLG plates used. To test the technical ease and feasibility of bonding two plates together with a piece of thin glass as a spacer, 0.15-mm thick, 22-mm square micro cover glass from VWR was inserted between two pre-tinned 2.32-mm SLG plates and hot-pressed on the mini-press. Results of several repeated experiments indicated the addition of the spacer did not cause any problems. Additional solder alloy can be applied onto the “dip” caused by the spacer along the edges with a solder iron. Or, thicker solder alloy coating on the two SLG plates can be used to “automatically” flow out to the dip during hot-pressing.

The bonding strength of the laminates fabricated with the solder-glass wetting+hot-press process was examined manually with a simple “thumb-hand twisting” with two hands. All the laminates of 1″×3″ SLG plates did not break apart at the bonded region. In fact, it was the 2.32-mm-thick glass plates themselves that would break upon high force, not the bonds. These tests and observations are qualitatively indicative of high bonding strength. A mechanical “lap sheer” test is the next step of testing.

Bonding with rectangular or square SLG slides was conducted to simulate the “mini-module.” The quality of complete edge sealing was found to depend highly on the quality, coverage completeness, thickness, and uniformity. Another important factor was the fluidity of the applied solder alloy. Repeated rubbing of the solder alloy (to improve surface wetting and coverage) on the heated SLG plate substrates (at 150°-160° C.) with a hot glass rod or solder iron tip at 232° C. or higher could result in formation of particles (suspected to be oxides) and reduced fluidity. Such particle formations and reduced fluidity decreased the bonding properties as evidenced by the reduced or absence of free-flow under hot-pressing.

As a result of the above, modification of the processing conditions, e.g. the control of temperatures resulted. The final working process used 140° C. for glass substrate heating, 177° C. for solder iron tip heating, and wire of Cerroseal 35 solder alloy. Although the current manual application process cannot avoid certain rubbings on the glass surface, the applied alloy strips were able to retain good fluidity, which allows good bonding when coupling (pairing-up) is conducted on the vacuum laminator (and/or mini-press).

On the other hand, thin WS118 foil (about 0.11 mm thick) cut into 2-3 mm wide strips were also used to lay on the SLG plates, but produced laminates with sub par adhesion (bonding). The foils are cleaned with isopropyl alcohol and acetone before use.

### EXAMPLE 4

### Cobalt Based Moisture Indicators

A thin coating of CoCl₂.6H₂O from isopropyl alcohol solution is applied onto the SLG plates in preparation for solder alloyed laminates. Other methods attempted involved employing a Dyneon THV 220A fluoropolymer and 3M® double-side tape (3M Corporation, St. Paul, Minn.) or VHB® tape (3M Corporation, St. Paul, Minn.) for CoCl₂ loading.

### EXAMPLE 5

### Preparing a Control

Control samples were prepared using the fast-cure cycle in a vacuum laminator with a relative humidity (“RH”) indicator card ((#HI 6203) by Süd-Chemie Performance Packaging) or CoCl₂ coating and with the solder alloy strips replaced with commercial edge sealant tape, HelioSeal PVS-101-S (0.8-mm thick×5-mm wide) provided by ADCO.

### EXAMPLE 6

### Moisture-Blocking Test and Color Change Monitoring

Two methods were undertaken to assess moisture uptake by the soldered plates. The first method required application of damp heat (“DH”) at 85° C./85% RH to the soldered plates in an ESPEC® environment chamber (ESPEC Kabushiki Kaisha Corporation, Osaka, Japan). (IEC 61646 module qualification standard: 85° C./85% RH for 1000 h).

The second method subjected the soldered plates to a highly accelerated stress test (“HAST”) at about 110 to 118° C./100%RH/at about 6 to 11 psi in an All American Electric 25× pressure steam sterilization chamber (“pressure cooker”).

After soldered SLG plates were subjected to one of the two moisture-blocking tests, visual observation of color change on either the RH indicator card or CoCl₂ coating were evaluated. Further, color indices were measured for the CoCl₂ coating on a HunterLab's UltraScan spectrocolorimeter.

Two sample sets with CoCl₂ coating as moisture indicators were prepared and tested separately, one set in an ESPEC environment chamber at DH 85° C./85% RH (without additional external pressure), and the second set in the pressure cooker. Samples of “Control Samples” with RH indicator card or CoCl₂ coating encapsulated with ADCO edge sealant tape were also prepared and tested simultaneously. Because of being limited by the m.p.=118° C. of the Cerroseal 35 solder alloy, the temperature (T) and pressure (P) settings on the pressure cooker were also limited. Furthermore, due to the inherent “high-low” swing of the cooker, the T and P being realized are in the range of 110°-116° C. and about 6 to 11 psi, while the RH level was assumed to be 100%. The samples were inspected visually and measured with color indices periodically during the course of DH exposure.

### (a) DH in ESPEC at 85° C./85% RH

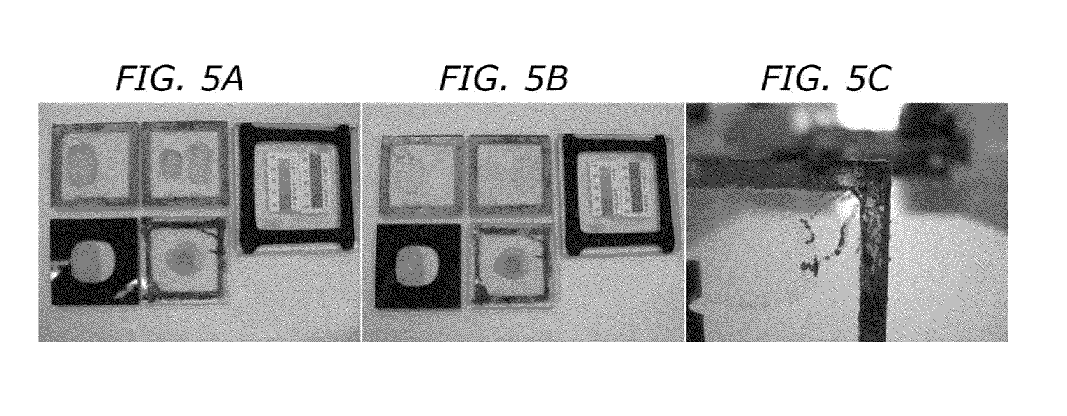

Two samples exhibited color change from initial purple blue to pink and then color fading within the first 100 h. Some areas of the Cerroseal 35 solder alloy strips on these two samples were porous as a result of incomplete surface wetting, which could be the primary cause for moisture ingress. An exemplary sample (Co—SQ6) failed in between 600 h and 800 h, while the control remained unchanged as determined from the color index measurements. FIG. 5A illustrates samples exposed to ESPEC for DH=0 h and FIG. 5B illustrates samples exposed to ESPEC for DH=148 h. FIG. 5C illustrates a porous region on the alloy strips resulting from incomplete surface wetting and non-uniform coating.

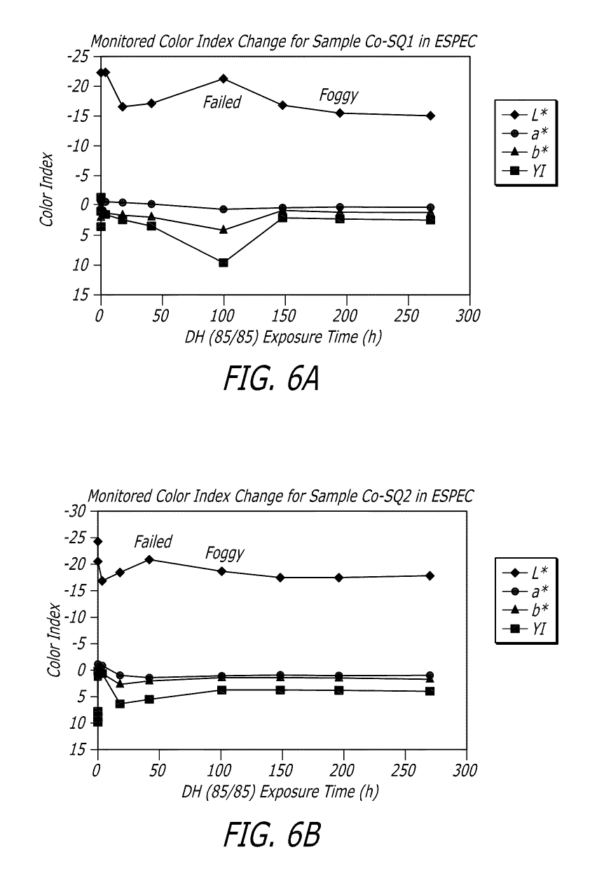

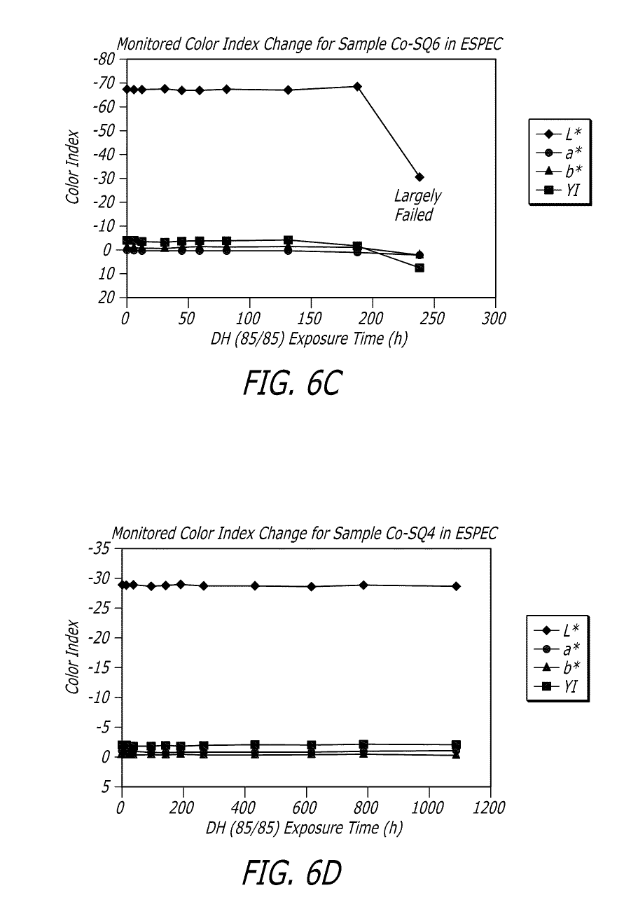

FIGS. 6A-D illustrate color index changes for four samples Co—SQ1 (A), Co—SQ2 (B), Co—SQ6 (C) and Co—SQ4 (D). The color index changes were measured for the CoCl₂ coatings within the three Cerroseal 35 and one ADCO edge sealant sealed glass/glass samples. The color change of CoCl₂ from purple-blue to pink and then nearly colorless reflected moisture ingress.

### (b). HAST in Pressure Cooker at 110°-116° C./100%RH/about 6 to 11 psi

The HAST test is a very harsh test, and may be useful for testing or ranking material stability. The relative acceleration factor (RAF) with the temperature at 115° C. was estimated to be 8×, when compared to the DH at 85° C., using the approximation: every 10° C. increase results in a doubled reaction rate. The RAFs on RH and pressure were not established. It is possible that the overall RAF exceeds 15× (vs. 85° C./85% RH).

The samples survived the about the first 70 min that shot over 118° C. and 12 psi, when the temperature control was set at about 2.7 (max 8). The power control was then turned down to about 2.4. As a result of the swinging in temperature and pressure, the temperature at high end was still close to 117° C. It is possible that a temperature close to the m.p. decreased the moisture blocking ability of the edge sealing, because softening or partly melting of the solder alloy. The test conditions used thus would be considered as the worst situation. One sample failed at first 20 h, and two more failed at 44 h. The third failed at 70 h. The failed alloy sealing strips exhibited darkened regions, suggesting moisture ingress induced degradation and interfacial failure under steam pressure. The three Control samples with ADCO edge sealant tape are substantially intact at HAST=70 h, with the exception of one sample showing “pushed-in” distortion of the ADCO edge sealant tape caused by the steam pressure in the first 20 h.

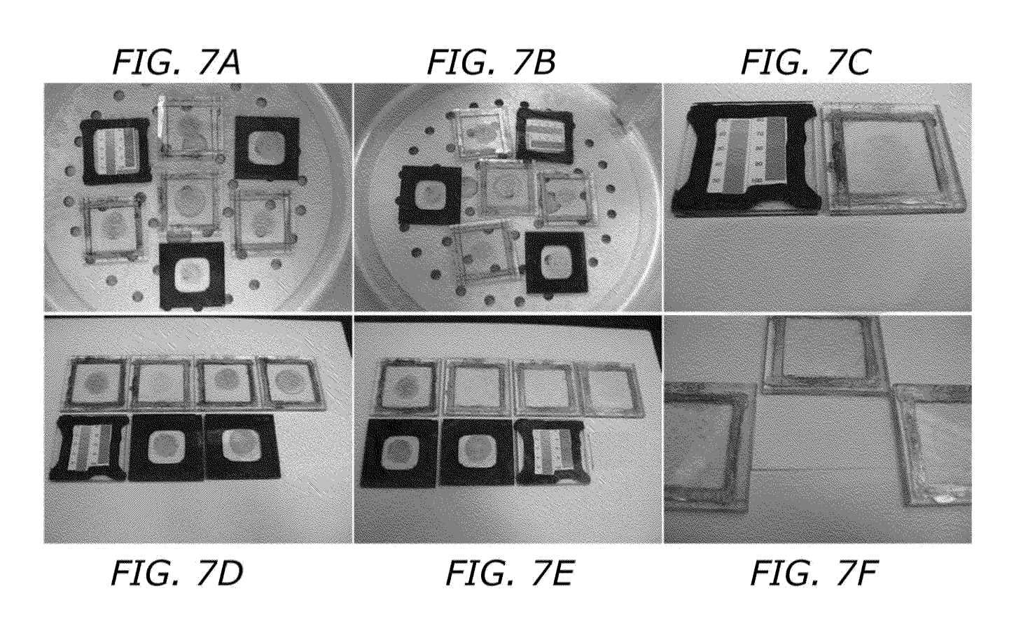

FIGS. 7A-F illustrate results of HAST studies. FIG. 7A illustrates HAST at 0 h and FIG. 7B HAST at 1 hr. FIG. 7C illustrates control sample with distorted sealant tape and a failed sample at 20 hr. FIG. 7D illustrates HAST at 20 hr and FIG. 7E HAST at 44 hr. FIG. 7F illustrates darkened regions on the alloys strips when the samples failed.

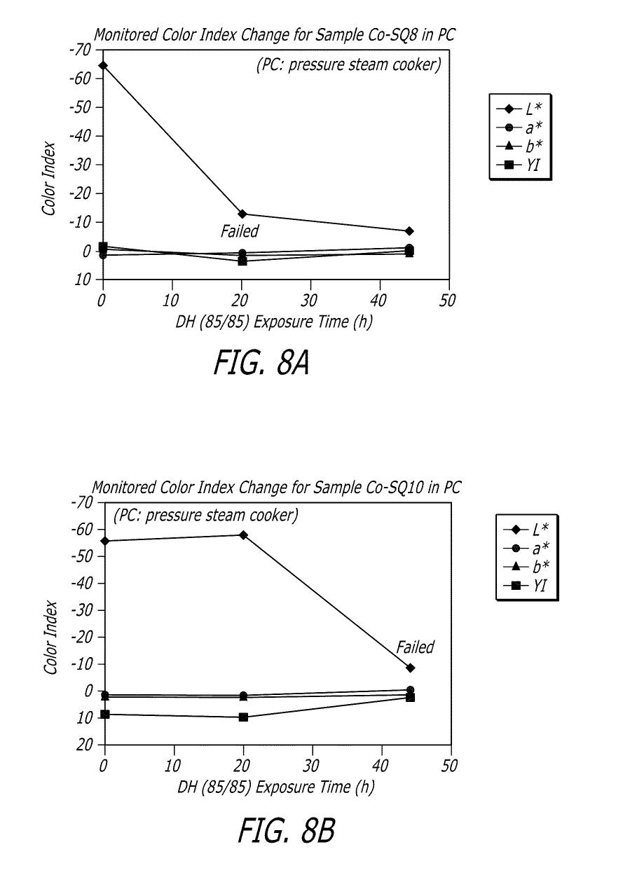

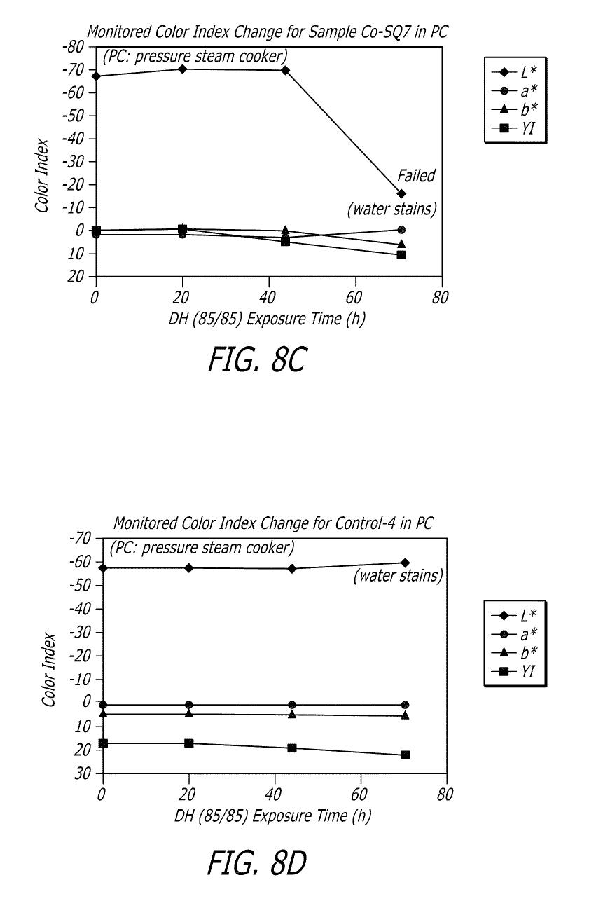

FIGS. 8A-D illustrate color index changes for four samples Co—SQ8 (A), Co—SQ10 (B), Co—SQ7 (C) and Co—SQ4 (D). The color index changes were measured for the CoCl₂ coatings within three HAST-tested glass/glass samples sealed with Cerroseal 35 and one ADCO edge sealant. The color change of CoCl₂ from purple-blue to pink and then nearly colorless reflected moisture ingress.

Also noteworthy was that after the above tests were finished, the pressure cooker was further test-run at the lowest power setting (1), giving a max about 112° C. and about 7.8 psi.

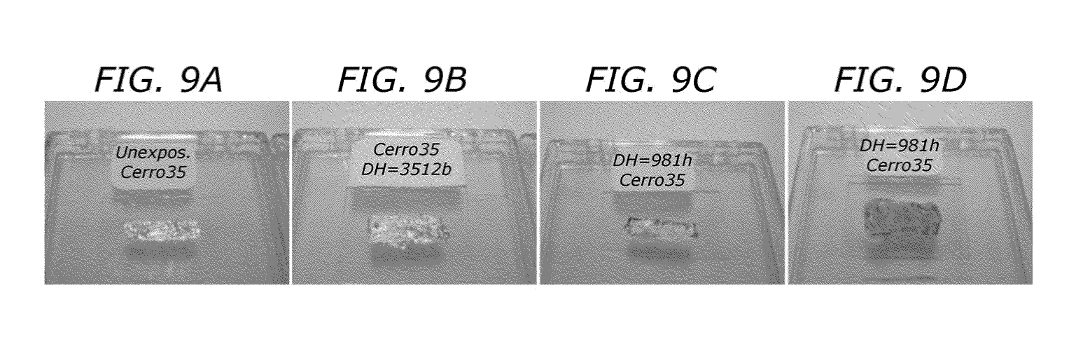

Certain levels of material degradation were seen by the formation of “black” dots or darkened regions on the 85° C./85% RH-exposed Cerroseal 35 alloy/microslide test samples, as seen in FIGS. 9A-D (Cerro35 is Ceroseal 35). FIG. 9A illustrates and unexposed sample; FIG. 9B illustrates a sample exposed to DH 85° C./85% RH for 351 hr; FIG. 9C illustrates a sample exposed to DH 85° C./85% RH for 981 hr; and FIG. 9D illustrates a sample in two unlaminated slides. Sheet resistance measurements using four-linear probe indicated a change from about 9.3 mili-ohm/square (lowest value) on the unexposed alloy to 21.5 mili-ohm/square on DH=351 h and 123.6 mili-ohm/square on DH=981 h sample. The chemical reactions for the degradation were suspected to be oxidation and hydrolysis.

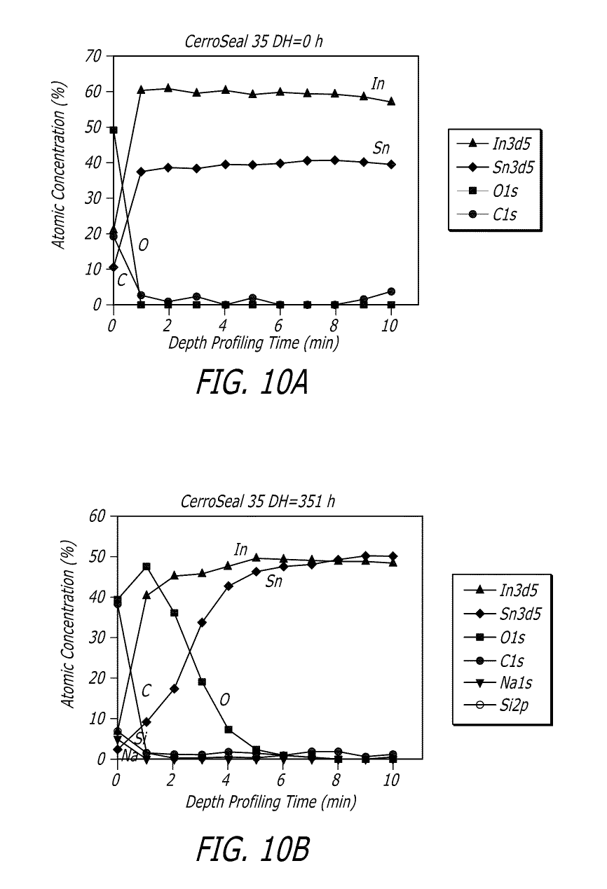

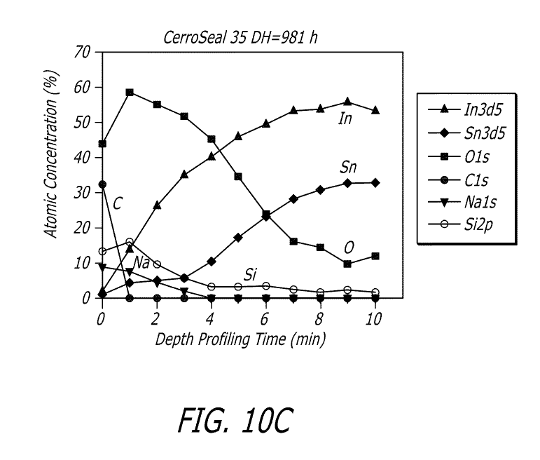

The results of x-ray photoelectron Spectroscopy (XPS) depth profile analysis of the unexposed and DH-exposed Cerroseal 35 samples on microslides illustrated in FIGS. 9A-D are provided in FIGS. 10A-C, showing the increased compositional/chemical changes resulting from oxidation and hydrolysis of the solder alloy by the damp heat exposure. FIG. 10A illustrates Cerroseal35 on a microslide after DH=0 h, FIG. 10B illustrates Cerroseal35 on a microslide after DH=351 h and FIG. 10C illustrates Cerroseal35 on a microslide after DH=981 h.

### EXAMPLE 7

### Bonding Glass Plates Using 0.2% Gold

A solar cell module is formed using a SLG glass plate, an ethyl vinyl acetate layer, a photovoltaic cell and a second SLG plate. The components are layered as illustrated in FIG. 1 with SLG glass plates on top and bottom. The SLG plates are cleaned using soap and water before the components are layered.

CERROSEAL® 35 (50% Sn/50% In) is diluted with 0.2% gold giving a alloy of 49.9% Sn/49.9% In/0.2% Au. This alloys is used to solder the edge gap between the two SLG plated. Soldering is accomplished with a solder iron at about 115° C. to about 127° C. After soldering the using the alloy, the plates are cooled, and HELIOSEAL® PVS 101 is applied around the edge of the solar cell to provide an additional layer of moisture protection.

### EXAMPLE 8

### Bonding Glass Plates Using 0.5% Gold

A solar cell module is formed using a SLG glass plate, an ethyl vinyl acetate layer, a photovoltaic cell and a second SLG plate. The components are layered as illustrated in FIG. 1 with SLG glass plates on top and bottom. The SLG plates are cleaned using soap and water before the components are layered.

CERROSEAL® 35 (50% Sn/50% In) is diluted with 0.5% gold giving a alloy of 49.25% Sn/49.25% In/0.5% Au. This alloys is used to solder the edge gap between the two SLG plated. Soldering is accomplished with a solder iron at about 115° C. to about 127° C. After soldering the using the alloy, the plates are cooled, and HELIOSEAL® PVS 101 is applied around the edge of the solar cell to provide an additional layer of moisture protection.

### EXAMPLE 9

### Bonding Glass Plates Using Nanofoil

A solar cell module is formed using a SLG glass plate, an ethyl vinyl acetate layer, a photovoltaic cell and a second SLG plate. The components are layered as illustrated in FIG. 1 with SLG glass plates on top and bottom. The SLG plates are cleaned using soap and water before the components are layered.

A nanofoil system as illustrated in FIG. 3B is used to bond the glass plates. First, a copper brazing layer is distributed along the solder contact points of both pieces of glass. Then, a nanofoil is laid along the brazing strip of the first piece of glass. The sandwich of components is assembled. Then, a momentary intense heat is applied to the nanofoil area and the glass plates are bonded and able to be handled within a matter of second. At this point an edge sealant can be used to further seal the edges of the bonded cells. HELIOSEAL® PVS 101 is used as the edge sealant.

The terms “a,” “an,” “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of the invention otherwise claimed. No language in the specification should be construed as indicating any non-claimed element essential to the practice of the invention.

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

Certain embodiments of this invention are described herein, including the best mode known to the inventors for carrying out the invention. Of course, variations on these described embodiments will become apparent to those of ordinary skill in the art upon reading the foregoing description. The inventor expects skilled artisans to employ such variations as appropriate, and the inventors intend for the invention to be practiced otherwise than specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

Specific embodiments disclosed herein may be further limited in the claims using consisting of or and consisting essentially of language. When used in the claims, whether as filed or added per amendment, the transition term “consisting of excludes any element, step, or ingredient not specified in the claims. The transition term “consisting essentially of limits the scope of a claim to the specified materials or steps and those that do not materially affect the basic and novel characteristic(s). Embodiments of the invention so claimed are inherently or expressly described and enabled herein.

Furthermore, numerous references have been made to patents and printed publications throughout this specification. Each of the above-cited references and printed publications are individually incorporated herein by reference in their entirety.

In closing, it is to be understood that the embodiments of the invention disclosed herein are illustrative of the principles of the present invention. Other modifications that may be employed are within the scope of the invention. Thus, by way of example, but not of limitation, alternative configurations of the present invention may be utilized in accordance with the teachings herein. Accordingly, the present invention is not limited to that precisely as shown and described.

We claim:

1. A method of bonding a first piece of glass and a second piece glass of a photovoltaic cell module comprising:
providing said first piece of glass having a planar surface;
providing said second piece of glass having a second planar surface;
providing a photovoltaic cell between said first piece of glass and said second piece of glass;
providing an amount of solder to at least one solder contact area disposed on at least one of said first or second pieces of glass, wherein said solder comprises gold;
heating said solder to about the melting or working point of said solder; and
bonding said first piece of glass and said second piece glass thereby sealing said photovoltaic cell module from moisture.

2. The method of claim 1, wherein said solder comprises tin, indium or a combination thereof.

3. The method of claim 2 wherein gold is present in the solder at an amount of about 0.1% to about 1%.

4. The method of claim 3 wherein the solder has a composition of about 49.9% Sn/49.9% In/0.2% Au.

5. The method of claim 3 wherein the solder has a composition of about 49.25% Sn/49.25% In/0.5% Au.

6. The method of claim 1, wherein the solder further comprises glass comprises PbO, ZnO, B₂O₃, Bi₂O₃, Ag₂O, Al₂O₃, Li₃O, NaO, or SnO; or a combination thereof.

7. The method of claim 1, wherein a polymer encapsulating layer is located between said first piece of glass and said photovoltaic cell, and wherein said polymer encapsulating layer comprises ethyl vinyl acetate.

8. The method of claim 1, wherein the method is performed in an inert environment.

9. A method of bonding a first piece of glass and a second piece glass of a photovoltaic cell module comprising:
providing said first piece of glass having a planar surface;
providing said second piece of glass having a second planar surface;
providing a photovoltaic cell between said first piece of glass and said second piece of glass;
providing at least one brazing strip to at least one solder contact area disposed on said first piece of glass and said second pieces of glass;
further providing at least one strip of solder foil to at least one brazing strip;
heating said at least one strip of solder foil to about the melting or working point of the solder foil; and
bonding said first piece of glass and said second piece glass thereby sealing said photovoltaic cell module from moisture.

10. The method of claim 9, wherein said solder comprises tin, indium or a combination thereof.

11. The method of claim 9, wherein the heating step occurs in less than about one second.

12. The method of claim 9, wherein the solder further comprises glass comprises PbO, ZnO, B₂O₃, Bi₂O₃, Ag₂O, Al₂O₃, Li₃O, NaO, or SnO; or a combination thereof.

13. The method of claim 9, wherein a polymer encapsulating layer is located between said first piece of glass and said photovoltaic cell, and wherein said polymer encapsulating layer comprises ethyl vinyl acetate.

14. The method of claim 9, wherein the method is performed in an inert environment.

15. A photovoltaic cell module comprising:
a first piece of glass;
a second piece of glass; and
a photovoltaic cell located between said first and second pieces of glass;
a gap around the periphery and between said first and second pieces of glass filled with a solder,
wherein the solder seals said photovoltaic cell module from moisture.

16. The photovoltaic cell module of claim 15, wherein said solder comprises tin, indium or a combination thereof.

17. The photovoltaic cell module of claim 16, wherein the solder further comprises gold present at an amount of about 0.1% to about 1%.

18. The photovoltaic cell module of claim 17, wherein the solder has a composition of about 49.9% Sn/49.9% In/0.2% Au.

19. The photovoltaic cell module of claim 17, wherein the solder has a composition of about 49.25% Sn/49.25% In/0.5% Au.

20. The photovoltaic cell module of claim 15, wherein the solder further comprises glass comprises PbO, ZnO, B₂O₃, Bi₂O₃, Ag₂O, Al₂O₃, Li₃O, NaO, or SnO; or a combination thereof.

21. The photovoltaic cell module of claim 15, wherein a polymer encapsulating layer is located between said first piece of glass and said photovoltaic cell, and wherein said polymer encapsulating layer comprises ethyl vinyl acetate.

22. The photovoltaic cell module of claim 15, further comprising a brazing strip between said first piece of glass and said solder.

23. The photovoltaic cell module of claim 15, further comprising a brazing strip between said second piece of glass and said solder.
